(19) United States
(12) Patent Application Publication
(10) Pub. No.: US 2006/0231913 A1
(43) Pub. Date: Oct. 19, 2006

(54) Method for determining wavelengths of light incident on a stacked photodetector structure

(75) Inventors: Philip A. Wilsey, Cincinnati, OH (US); Fred R. Beyette JR., Cincinnati, OH (US); Christopher James Fearing, Cincinnati, OH (US)

Correspondence Address: GUERIN & RODRIGUEZ, LLP, 5 MOUNT ROYAL AVENUE, MOUNT ROYAL OFFICE PARK, MARLBOROUGH, MA, 01752, US

(73) Assignee: Clifton Labs, Inc., Cincinnati, OH (US)

(21) Appl. No.: 11/401,704

(22) Filed: Apr. 11, 2006

Related U.S. Application Data
(60) Provisional application No. 60/670,741, filed on Apr. 13, 2005.

(51) Int. Cl. H01L 31/06

(52) U.S. Cl. 257/461; 257/E31.121

(57) ABSTRACT

Described are a device and a method for determining a wavelength of light incident on a device having an upper photodiode vertically disposed on a lower photodiode. Currents generated by the upper and lower photodiodes in response to the incident light are measured. The wavelength of the light is determined in response to the measured currents and a predetermined correspondence between the currents from the photodiodes as a function of wavelength. In one embodiment, bias voltages applied to the photodiodes are changed and modified currents are measured. The wavelength is determined in response to the measured currents and a predetermined correspondence between the currents from the two photodiodes as a function of wavelength and bias voltage.

### RELATED APPLICATION

This application claims the benefit of the filing date of co-pending U.S. Provisional Application Serial No. 60/670,741, filed Apr. 13, 2005, titled “A Direct Method to Compute Optical Wavelengths,” the entirety of which provisional application is incorporated by reference herein.

### FIELD OF THE INVENTION

The invention relates generally to the spectral characterization of light. More particularly, the invention relates to the determination of wavelength using vertically stacked photodetectors in optically active materials.

### BACKGROUND OF THE INVENTION

Digital imaging systems typically utilize one or more sensors having an array of photodetectors. Each photodetector is associated with an image pixel. Color imagers generally employ photodetector arrays in which a color filter is fabricated over each photodetector. The wavelength range of each color filter varies according to the position of the photodetector in the array. For example, in imaging systems utilizing red-green-blue (RGB) color data, each photodetector has a red, green or blue filter so that only optical energy within the wavelength band passed by the filter is detected. FIG. 1 illustrates a Bayer filter pattern used in many conventional color cameras providing RGB image data. Each photodetector 14 in a group of pixels 10 generates a photocurrent responsive to the optical power incident on the photodetector and in the wavelength band of a corresponding color filter. Thus red photodetectors generate a photocurrent responsive to red light, green photodetectors generate photocurrent responsive to green light, and blue photodetectors generate photocurrent responsive to blue light. For example, a blue pixel 14 within the group of pixels 10 can only record an analog value for blue incident light. To produce an RGB value for the blue pixel 14, the blue value measured by the pixel is coupled with an average of the surrounding red values from adjacent red pixels and the average of the surrounding green values from adjacent green pixels.

Using multiple photodetectors in the image plane to generate an RGB value results in color artifacts and diminished color clarity. Image capture sensors have been developed which rely on the variation in the absorption coefficient of a sensor material as a function of wavelength. More specifically, the sensors are based on the variation in the penetration depth of light as a function of wavelength. For example, a detector structure has been developed in which three vertically stacked photodetectors are used to detect three colors. Each photodetector is fabricated with a certain thickness and doping concentration. The photodetector nearest the surface of the structure senses blue light, the photodetector in the middle of the stack senses green light, and the photodetector at the greatest depth from the surface senses red light. Optical filtering is employed to improve discrimination of the blue, green and red detection bands. Advantageously, each RGB pixel is defined by a single photodetector stack and, therefore, higher image quality is achieved; however, the sensor design is complex and optimized only for one set of wavelength bands. Moreover, such sensors require expensive manufacturing processes capable of fabricating tightly controlled layer thicknesses and doping concentrations necessary to achieve sensitivity to the three defined wavelength bands.

### SUMMARY OF THE INVENTION

In one aspect, the invention features a method for determining a wavelength of light incident on a semiconductor device comprising an upper region of a first conductivity type disposed on a lower region of a second conductivity type opposite the first conductivity type. A first current generated in response to light that is absorbed in the upper region is measured and a second current generated in response to light that is absorbed in the lower region is measured. The wavelength of the light incident on the semiconductor device is determined in response to the measured first and second currents and a predetermined correspondence between the first and second currents as a function of wavelength.

In another aspect, the invention features a method for determining a wavelength of light incident on a semiconductor device comprising an upper photodiode vertically disposed on a lower photodiode. The upper photodiode is biased at a first bias voltage and the lower photodiode is biased at a second bias voltage. A first current generated by the upper photodiode and a second current generated by the lower photodiode responsive to the light incident on the semiconductor device are measured. At least one of the first bias voltage and the second bias voltage are changed. A modified first current and a modified second current responsive to the light incident on the semiconductor device are measured. The wavelength of the light incident on the semiconductor device is determined in response to the measured first and second currents, the measured modified first and second currents, and a predetermined correspondence between the measured and modified first and second currents as a function of wavelength and bias voltage.

In yet another aspect, the invention features a device for determining a wavelength of light. The device includes a semiconductor structure, a first current module, a second current module and a processor. The semiconductor structure has an upper photodiode vertically disposed on a lower photodiode. The first current module communicates with the upper photodiode to measure a first current generated in the upper photodiode in response to light that is incident on the semiconductor structure. The second current module communicates with the lower photodiode to measure a second current generated in response to the light that is incident on the semiconductor structure. The processor communicates with the first and second current modules to determine the wavelength of the light that is incident on the semiconductor structure according to the measured first and second currents and a predetermined correspondence between the first and second currents as a function of wavelength.

In still another aspect, the invention features a method for determining a wavelength of light incident on an optically active material having a plurality of stacked regions of alternating conductivity type. For each region, a current generated in response to light that is absorbed in the region is measured. The wavelength of the light incident on the optically active material is determined according to the measured currents and a predetermined correspondence between the measured currents as a function of wavelength.

### BRIEF DESCRIPTION OF THE DRAWINGS

The above and further advantages of this invention may be better understood by referring to the following description in conjunction with the accompanying drawings, in which like numerals indicate like structural elements and features in the various figures. The drawings are not necessarily to scale, emphasis instead being placed upon illustrating the principles of the invention.

FIG. 1 illustrates a Bayer color filter pattern used in conventional color cameras to generate RGB image data.

FIG. 2 is a cross-sectional illustration of a dual photodetector semiconductor structure having a stacked series of PN junctions with which a method for determining a wavelength of light incident according to the invention can be practiced.

FIG. 3 shows the optical absorption coefficient of silicon as a function of wavelength.

FIG. 4 illustrates the distribution of generated electron-hole pairs as a function of silicon substrate depth for various wavelengths.

FIG. 5 is a graphical depiction of the separation of two photodetector regions for a stacked photodetector device.

FIG. 6 is a graphical representation the currents generated from the upper and lower photodetectors of FIG. 2 and the ratio of the currents as a function of wavelength.

FIGS. 7A, 7B and 7C illustrate the photodetector structure of FIG. 2 for three different diffusion boundary depths realized through the application of different photodetector bias voltages.

FIG. 8 is a cross-sectional illustration of the structure of FIG. 2 showing virtual photodetectors achieved by changing the bias voltages for the two photodetectors.

FIG. 9 is a schematic illustration of an exemplary circuit for changing bias voltages and measuring the currents of the two photodetectors in the structure of FIG. 2.

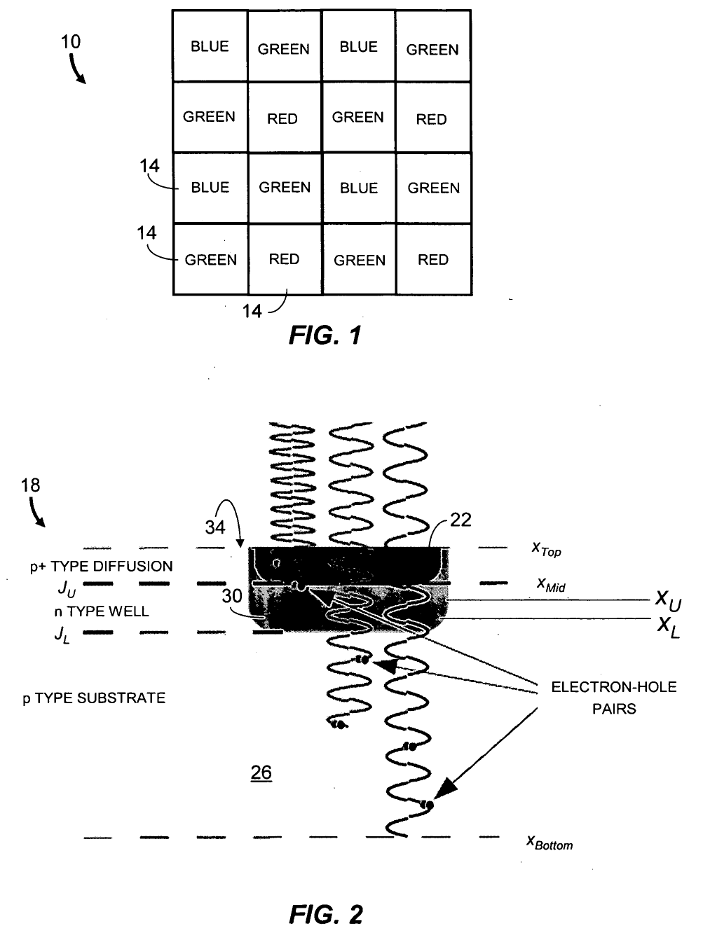

### DETAILED DESCRIPTION

In brief overview, the present invention relates to a method and a photodetector device for determining wavelength and optical power of an optical signal. The device can be fabricated in a variety of optically active materials. For example, the device can be fabricated using standard VLSI techniques because strict control of photodetector layer thicknesses and doping concentrations is not required. The device provides true wavelength responsivity over a wide spectral range. Signal processing circuitry enables both wavelength and optical power to be sensed by each dual photodetector element in a detector array. Although described below primarily as a silicon semiconductor device with a spectral range limited to visible and near infrared (IR) wavelengths, other embodiments employ other column IV materials, III-V materials, II-VI materials, and possible combinations of these materials such that wavelength sensitivity can be tailored to cover a wide range of operating wavelengths extending from ultraviolet (UV) wavelengths to the long-IR wavelengths.

Optical filters are not required to enable determination of wavelength. Each photodetector device provides all the information to determine the wavelength of the incident light. Thus averaging among a group of pixels is not necessary. Consequently, arrays of stacked photodetectors according to the invention yield improved image quality over conventional imaging arrays.

The device can be fabricated as a structure having only two vertically stacked photodetectors. Fabrication can be implemented using standard complementary metal oxide semiconductor (CMOS) fabrication techniques. Contrary to other stacked photodetector sensors, the thicknesses of the photodetector layers do not depend on operating wavelengths. Instead, the two photodetectors represent measuring points in the substrate where the concentrations of electron hole pairs (EHPs) are determined. By measuring current from both photodetectors at different bias voltages, various wavelengths (or wavelength bands) and the optical power at those wavelengths can be determined.

Operation at wavelengths outside the spectral sensitivity of a detector array using one material (e.g., silicon) can be achieved with a separate photodetector array connected to external signal processing circuitry. Alternatively, higher frame rates can be achieved for a given semiconductor material using a second photodetector array with separate signal processing circuitry. The elimination of external filters, cooling systems, and multiple sensors for different spectral bands results in improved reliability, lower cost, and high performance colorimetric imaging in small imagers. These photodetectors enable many of the benefits of multispectral technology without complex architectures relying on spectrometers, multi-channel electronics and high bandwidth communication links. Instead, only two channels of information are used to determine wavelength.

FIG. 2 illustrates a cross-section of a photodetector structure 18 including a stacked series of PN junctions. The illustrated layer structure 18 is common to the cross-section of metal oxide semiconductor (MOS) devices implemented using a standard CMOS fabrication process although the photodetector structure 18 can be implemented in other semiconductor material systems. The alternating pattern of p-type layers 22, 26 and n-type layers 30 can be fabricated in a homogeneous semiconductor using implantation or diffusion processes to establish the layer types and thicknesses, although other fabrication processes can be employed to generate the illustrated device cross-section. For example, epitaxial growth technologies are better suited for fabrication of heterogeneous semiconductor devices that have a similar layer structure and can be used for high speed detection of optical signals in mid IR to far IR wavelength ranges.

If the photodetector structure 18 is irradiated with light at normal incidence and an optical power P_{In}, the number of photons per second (N) incident on the photodetector surface 34 is given by

$$N = \frac{{P}_{In}}{{E}_{photon}} = \frac{{P}_{In} λ}{hc} \qquad ( 1 )$$

where Eₚₕₒₜₒₙ the photon energy, λ is the wavelength of the photons, h is Planck's constant, and c is the speed of light in a vacuum. To absorb the incident photons and convert them to current, the photon energy Eₚₕₒₜₒₙ must be greater than the band-gap energy E_{g} of the semiconductor. Thus the following relationship must be satisfied for photon absorption to occur:

$$\frac{hc}{λ} > {E}_{g} \qquad ( 2 )$$

Each absorbed photon creates a single electron-hole pair (EHP). As illustrated in FIG. 2, the creation of EHPs does not occur at a single depth in the semiconductor. Instead, there is a wavelength dependent exponential distribution of optically-generated EHPs that corresponds to the penetration of light in the semiconductor. More specifically, the exponential distribution varies by wavelength such that longer wavelengths have a deeper average penetration depth.

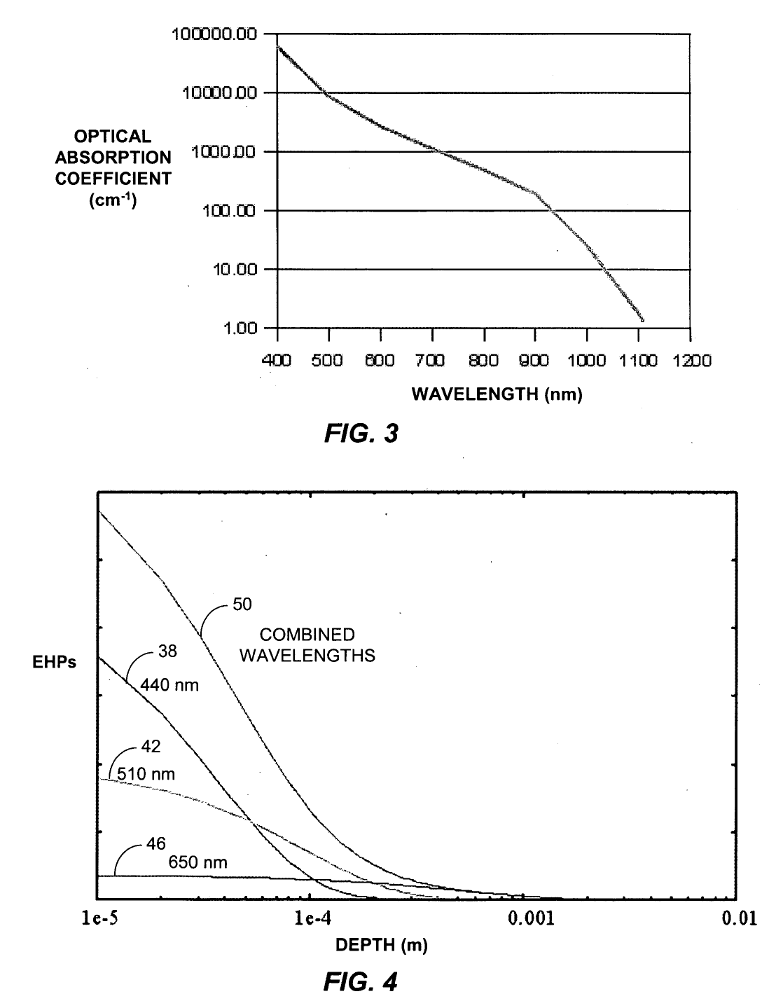

The optical absorption coefficient α for the distribution in silicon according to wavelength is depicted in FIG. 3. Thus, the number of photons per second N passing through a plane that is parallel to the semiconductor surface and located at a depth x is given by
N(x)=N₀e^{(-α*x)} (3)
where N₀ is the number of photons per second incident on the surface of the photodetector and α is the wavelength dependent absorption coefficient. If every absorbed photon is converted into an EHP, equation (3) also defines the distribution of optically generated EHPs in the semiconductor. FIG. 4 illustrates the distribution of the generated EHPs according to wavelength. Lines 38, 42 and 46 represent distributions for 440 nm, 510 nm and 650 nm wavelengths, respectively. Line 50 represents a distribution of the EHPs resulting from a combination of equal numbers of photons at each of the three wavelengths.

Analysis of the distribution of EHPs yields a spectral characterization of the light incident on the photodetector. More specifically, the number of photons per second N incident on the photodetector is determined by integration over depth and wavelength as:

$$N = {\int }_{minimum material wavelength}^{maximum material wavelengths} ( {\int }_{a}^{b} ( {N}_{0} {ⅇ}^{( - α * x )} ⅆ x ) ⅆ {α}_{λ} ) \qquad ( 4 )$$

where a and b are the minimum and maximum depths, respectively, defining a specific region of the semiconductor material, and minimum material wavelength and maximum material wavelength represent the lower and upper spectral wavelength limits for EHP generation caused by the light incident on the semiconductor material. The depths a and b can be selected to represent the upper or lower photodetector region of the semiconductor structure.

The photodetectors collect the EHPs and generate an electric current proportional to the rate of collection. A reverse bias voltage applied to the PN junction produces an electrical field that collects all of the optically generated EHPs within a minority carrier diffusion length of the field region. The collected EHPs make up the photocurrent (Iₒₚ) which is given by:
Iₒₚ=qAGₒₚt_{Active} (5)
where q is the charge of an electron, A is the area of the photodetector, Gop is the generation rate of EHPs per unit volume, and t_{Active} is the thickness of the region where EHP collection occurs. The product A t_{Active} defines the volume from which optically generated EHPs are collected to produce the photocurrent. Thus the current Iₒₚ is given by:
Iₒₚ=qN_{abs} (6)
where N_{abs} is the number of photons per second absorbed in the collection volume. N_{abs} can be calculated using Equation (3) by subtracting the photon rate at the bottom of the collection volume N(X=X_{bottom}) from the photon concentration at the top of the collection volume N(X=X_{Top).}

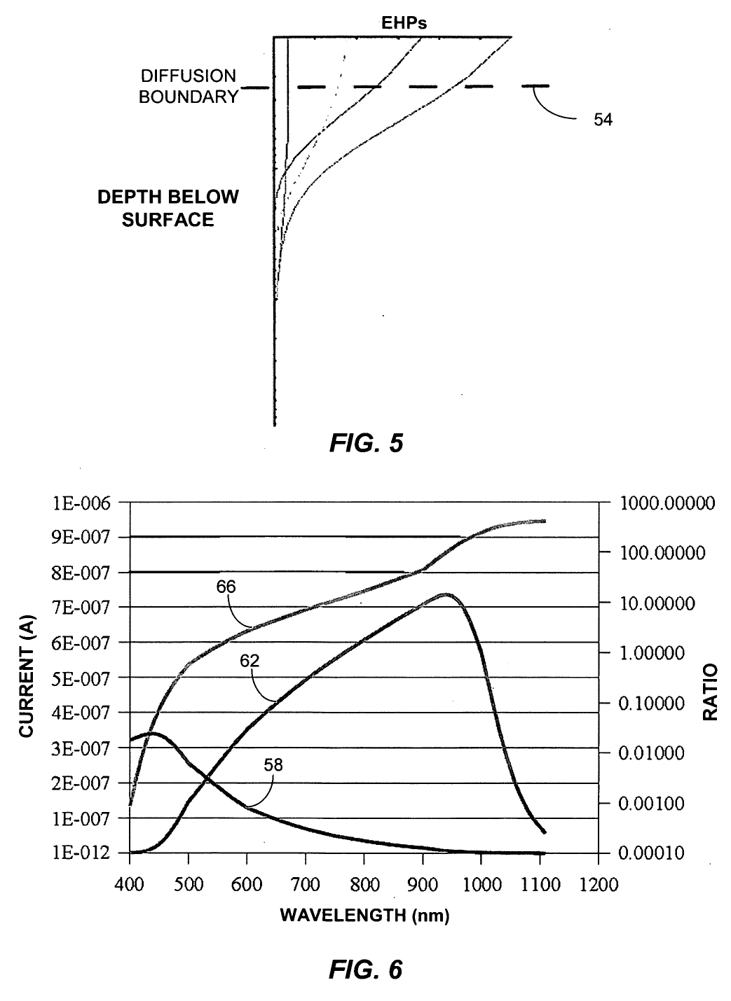

As described above, different wavelengths produce different distributions of photons in the device. Consequently, different wavelengths lead to different EHP concentrations in the active regions of the dual stacked photodetector structure of FIG. 2. For a fixed bias voltage on each photodetector, the measurable currents generated at each photodetector are proportional to the photon absorption rate in the active region (volume) of each photodetector. The dual photodetector can measure two volumes of the distribution of photons: an upper region and a lower region. FIG. 5 graphically depicts the separation of the two regions according to a “diffusion boundary line” 54. The vertical axis represents the depth below the surface of the stacked photodetector device and the horizontal axis represents the generated EHPs. EHPs above the diffusion boundary line 54 are collected by the upper photodetector while EHPs below the diffusion boundary line 54 are collected by the lower photodetector. The currents produced by each photodetector are used to characterize the total EHP distribution with respect to the diffusion boundary line in two ways. First, the sum of the two currents gives an accurate measurement of incident optical power on the device. Second, the relationship, or correspondence, between the two currents is used to determine the “shape” of the distribution of EHPs (and photons) and, therefore, can be analyzed to determine wavelength bands present in the incident light.

Current Boundary Method with Fixed Biasing

As described above, different wavelengths yield different penetration depths. A single photodetector produces a current that is based on the photon absorption rate within its active volume. The photon absorption rate is based on wavelength and the optical power of the incident light. As a result, a single photodetector is not sufficient to determine wavelength based solely on the photon absorption rate. According to equations 1, 3, and 5; however, current measurements from two stacked photodetectors can be used to determine wavelength and optical power.

FIG. 6 graphically illustrates the current 58 generated from the upper photodetector and the current 62 generated by the lower photodetector depicted in the device 18 of FIG. 2 as a function of wavelength. Also shown is a ratio of the two photodetector currents 58, 62. The ratio is distinct for all values of wavelength from approximately 430 nm to the responsivity limit of silicon at approximately 1.1 μm. The ratio r of the photodetector currents is given by:

$$r = - \frac{{ⅇ}^{- α * {x}_{Bottom}} ( {ⅇ}^{α * {x}_{Mid}} - {ⅇ}^{α * {x}_{Bottom}} )}{{ⅇ}^{α * {x}_{Mid}} - 1} \qquad ( 7 )$$

where X_{Mid} is the depth defined between the interface of the p+ region and the n type well and the interface of the n type well and the p type substrate, and X_{Bottom} is depth of the bottom of the substrate.

The ratio r of the two photodetector currents defines the wavelength of the incident light. The optical power of the incident light is linearly proportional to the current in both photodetectors over an operational optical power range. Once the wavelength is known, the measured current from one of the photodetectors is used to determine the optical power Power as:

$$Power = \frac{{hcI}_{diode}}{( {ⅇ}^{- α * {x}_{Top}} - {ⅇ}^{- α * {x}_{Bottom}} )} \qquad ( 8 )$$

where I_{diode} is the current generated by one of the photodetectors, α is the absorption coefficient for the wavelength determined from the ratio r of currents, and X_{Top} and X_{Bottom} are the top and bottom depths that define the active thickness of the photodetector.

In the method described above, the ratio r is determined for a single current from each photodetector for a fixed bias voltage applied to each photodetector. This method can be suitable for applications in which only the average wavelength and optical power are desired.

Current Boundary Method with Multiple Biases

Referring again to FIG. 2, each photodetector has an associated photodiode junction depth. When a bias voltage is applied to the photodiode a charge region is created around the respective junction defining a region of the EHP distribution that is measured at that bias voltage. The regions can be adjusted by changing the bias voltages to measure different portions of the distribution. Using variable bias voltages, more spectral information for the incident light can be acquired. To calculate the charge region for each photodetector the following equations are used:

$$\begin{matrix}{x}_{U} = {J}_{U} + \sqrt{( \frac{( 2 * {ε}_{o} * {ε}_{r} * {V}_{0} + {V}_{b} )}{q} * ( \frac{{N}_{( a ( pplus ) )}}{( {N}_{( d ( nwell ) )} * ( {N}_{( a ( pplus ) )} + {N}_{( d ( nwell ) )} ) )} ) )} & ( 9 ) \\ {x}_{L} = {J}_{L} - \sqrt{( \frac{( 2 * {ε}_{o} * {ε}_{r} * {V}_{0} + {V}_{b} )}{q} * ( \frac{{N}_{( a ( psubstrate ) )}}{( {N}_{( d ( nwell ) )} * ( {N}_{( a ( psubstrate ) )} + {N}_{( d ( nwell ) )} ) )} ) )} & ( 10 )\end{matrix}$$

where X_{U} and X_{L} are the limits of the charge regions for the upper and lower photodetectors, J_{U} and J_{L} are the junction depths of the upper and lower photodetectors, εₒ is the permittivity of free space, εr is the dielectric constant of the semiconductor used, V₀ is the contact potential, V_{b} is the applied bias voltage (which can be independent for the upper and lower photodetectors), q is the charge of an electron; N₍ₐ₍ₚₚₗᵤₛ₎₎ is the doping of the p+ doped diffusion material, N_{(d(nwell)) is the doping of the n doped well region, and N}_{(a(psubstrate))} is the doping of the p doped substrate. By changing the bias voltages in equations (10) and (11), the regions contributing to the current flow for each photodetector are changed. Consequently, multiple current measurements can be made for each photodetector to determine the contributions to the upper and lower detector currents by narrow wavelength bands.

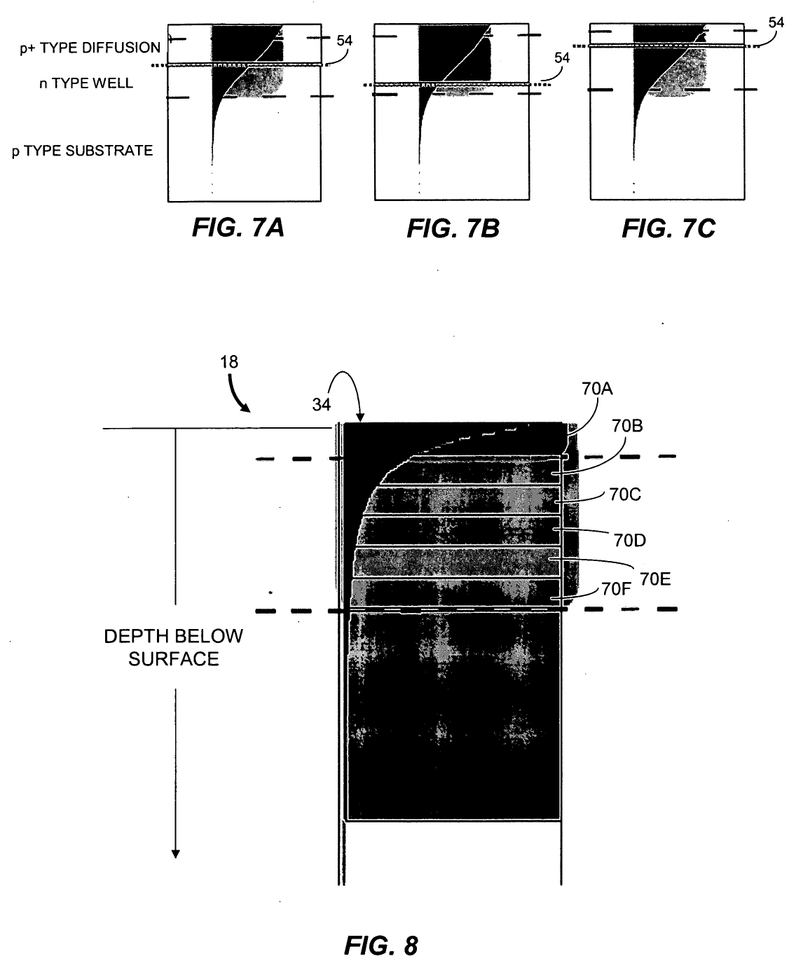

FIGS. 7A, 7B and 7C illustrate the photodetector structure of FIG. 2 for three different diffusion boundary depths achieved using different bias voltages. Superposed on each illustrated structure is a distribution of EHPs resulting from incident light. In FIG. 7A, a significant current is generated from each photodetector. FIG. 7B shows a diffusion boundary 54 positioned such that the current from the upper photodetector is substantially greater than the current from the lower photodetector. Conversely, FIG. 7C illustrates a diffusion boundary 54 positioned such that the current from the lower photodetector is substantially greater than the current from the upper photodetector. The bias voltages can be varied to achieve additional diffusion boundary positions so that the determined wavelength bands can be further narrowed.

The ability to analyze the currents from the two photodetectors for multiple bias voltages creates, in effect, multiple “virtual photodetectors” 70A through 70F (generally 70) as depicted in FIG. 8. Each virtual photodetector 70 has an effective thickness and a distinct effective depth. Using virtual photodetectors 70, a more detailed analysis of the distribution of EHPs is possible, leading to improved wavelength resolution in comparison to the fixed bias method. In one embodiment, portions of the distribution are used to achieve narrow wavelength detection bands. For example, 90% of light having a wavelength of 400 nm or less is absorbed in a certain depth based on doping concentrations and bias conditions. Similarly, 90% of light having a wavelength of410 nm or less is collected at a certain greater depth. In this manner data can be extracted from multiple bias readings. A relationship of upper photodetector current to lower photodetector current is generated for each bias setting. Using heuristic algorithms with each of the upper/lower photodetector relationships, optical power in the incident light for multiple narrow wavelength bands can be determined.

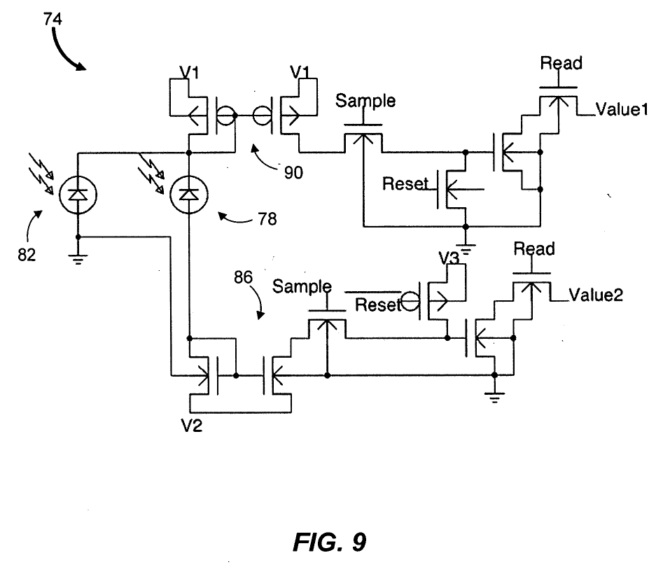

FIG. 9 shows an exemplary circuit 74 for changing bias voltages and measuring the currents of the two photodetectors 78, 82. Each detector 78, 82 is buffered by a current mirror. The NMOS current mirror 86 sinks a current from a precharged gate capacitance in relationship to the currents flowing through the upper photodetector 78. The PMOS current mirror 90 charges a gate capacitance in relationship to the current flowing through both photodetectors 78, 82. The circuit 74 provides two currents VALUE1 and VALUE2 proportional to the photodetector currents for the present bias voltages. These currents VALUE1 and VALUE2 can be provided to a current module adapted for determining the current amplitudes. The current module in turn provides the amplitudes to a processor or similar module to perform calculations (such as the determining the ratio of the currents) and other processing to determine the wavelength components of the incident light.

The circuit 74 also includes a bias control module (not shown) to control and change the bias voltages applied to the photodetectors. For example, the voltage at node V2 can be changed to alter the bias across the upper photodetector and move the diffusion boundary. Alternatively, the voltage at the common cathode of the photodetector photodiodes can be changed to move the diffusion boundary if the doping concentrations of the p+ region and the p type substrate are different.

While the invention has been shown and described with reference to specific embodiments, it should be understood by those skilled in the art that various changes in form and detail may be made therein without departing from the spirit and scope of the invention.

What is claimed is:

1. A method for determining a wavelength of light incident on a semiconductor device comprising an upper region of a first conductivity type disposed on a lower region of a second conductivity type opposite the first conductivity type, the method comprising:
measuring a first current generated in response to light that is absorbed in the upper region;
measuring a second current generated in response to light that is absorbed in the lower region; and
determining the wavelength of the light incident on the semiconductor device in response to the measured first and second currents and a predetermined correspondence between the first and second currents as a function of wavelength.

2. The method of claim 1 further comprising summing the first and second currents to determine an optical power of the light incident on the semiconductor device.

3. The method of claim 1 wherein the predetermined correspondence is a ratio of the first and second currents as a function of wavelength.

4. A method for determining a wavelength of light incident on a semiconductor device comprising an upper photodiode vertically disposed on a lower photodiode, the method comprising:
biasing the upper photodiode at a first bias voltage and biasing the lower photodiode at a second bias voltage;
measuring a first current generated by the upper photodiode and a second current generated by the lower photodiode in response to the light incident on the semiconductor device;
changing at least one of the first bias voltage and the second bias voltage; measuring a modified first current and a modified second current in response to the light incident on the semiconductor device; and
determining the wavelength of the light incident on the semiconductor device in response to the measured first and second currents, the measured modified first and second currents, and a predetermined correspondence between the measured and modified first and second currents as a function of wavelength and bias voltage.

5. The method of claim 4 further comprising summing the measured first and second currents to determine an optical power of the light incident on the semiconductor device.

6. The method of claim 4 further comprising summing the measured modified first and second currents to determine an optical power of the light incident on the semiconductor device.

7. The method of claim 4 wherein the step of measuring a modified first current and measuring a modified second current is repeated at least once for a different changed bias voltage and wherein the step of determining comprises determining the wavelength of the light incident on the semiconductor device in response to the measured first and second currents, a plurality of measured modified first and second currents, and a predetermined correspondence between the first and second currents as a function of wavelength and bias voltages.

8. A device for determining a wavelength of light, comprising:
a semiconductor structure having an upper photodiode vertically disposed on a lower photodiode;
a first current module in communication with the upper photodiode to measure a first current generated in the upper photodiode in response to light that is incident on the semiconductor structure;
a second current module in communication with the lower photodiode to measure a second current generated in response to the light that is incident on the semiconductor structure; and
a processor in communication with the first and second current modules to determine the wavelength of the light that is incident on the semiconductor structure in response to the measured first and second currents and a predetermined correspondence between the first and second currents as a function of wavelength.

9. The device of claim 8 wherein the processor comprises a ratio module to determine a ratio of the first and second measured currents.

10. The device of claim 8 further comprising a bias control module in communication with the processor, the first current module and the second current module, the bias control module configured to change a bias voltage applied to at least one of the upper photodiode and a bias voltage applied to the lower photodiode.

11. The device of claim 10 wherein the processor determines the wavelength of the light that is incident on the semiconductor structure in response to the measured first and second currents at each of a plurality of bias voltages applied to at least one of the photodiodes according to a predetermined correspondence between the first and second currents as a function of wavelength and bias voltages.

12. A device for determining a wavelength of light that is incident on a semiconductor device comprising an upper region of a first conductivity type disposed on a lower region of a second conductivity type opposite the first conductivity type, comprising:
means for measuring a first current generated in response to light that is absorbed in the upper region;
means for measuring a second current generated in response to light that is absorbed in the lower region; and
means for determining the wavelength of the light that is incident on the semiconductor device in response to the measured first and second currents and a predetermined correspondence between the first and second currents as a function of wavelength.

13. The device of claim 12 further comprising means for summing the first and second currents to determine an optical power of the light that is incident on the semiconductor device.

14. The device of claim 12 wherein the predetermined correspondence is a ratio of the first and second currents as a function of wavelength.

15. A method for determining a wavelength of light incident on an optically active material comprising a plurality of stacked regions of alternating conductivity type, the method comprising:
measuring, for each region, a current generated in response to light that is absorbed in the region; and
determining the wavelength of the light incident on the optically active material in response to the measured currents and a predetermined correspondence between the measured currents as a function of wavelength.

16. The method of claim 15 further comprising summing the measured currents to determine an optical power of the light incident on the optically active material.

17. The method of claim 15 wherein the optically active material is a semiconductor material.
